(19) United States
(12) Patent Application Publication
(10) Pub. No.: US 2026/0344465 A1
(43) Pub. Date: Oct. 29, 2026

(54) PACKAGE INCLUDING COMPOSITE INTERPOSER AND/OR COMPOSITE PACKAGING SUBSTRATE AND METHODS OF FORMING THE SAME

(71) Applicant: Taiwan Semiconductor Manufacturing Company Limited, Hsinchu (TW)

(72) Inventors: Chin-Hua WANG, New Taipei City (TW); Tsung-Yen LEE, Hemei Township (TW); Yu Chen LEE, Hsinchu City (TW); Ping Tai CHEN, Taipei City (TW); Shin-Puu JENG, Po-Shan Village (TW)

(21) Appl. No.: 19/735,959

(22) Filed: Jul. 9, 2026

Related U.S. Application Data
(62) Division of application No. 18/302,023, filed on Apr. 18, 2023.
(60) Provisional application No. 63/436,571, filed on Dec. 31, 2022.

(51) Int. Cl. H10W 70/60; H10W 70/685; H10W 90/00

(52) U.S. Cl. CPC H10W 70/614; H10W 70/611; H10W 70/685; H10W 90/00; H10W 90/401; H10W 90/791

(57) ABSTRACT

A chip package structure includes: a composite interposer including at least one in-interposer semiconductor chip including a respective semiconductor circuitry therein, a dielectric matrix laterally surrounding the at least one in-interposer semiconductor chip, a die-side redistribution structure located on a first side of the dielectric matrix, and a substrate-side redistribution structure located on a second side of the dielectric matrix; and at least one semiconductor die attached to the die-side redistribution structure through a respective array of solder material portions.

### RELATED APPLICATIONS

This application is a divisional application of U.S. Application Serial No. 18/302,023 entitled “Package Including Composite Interposer and/or Composite Packaging Substrate And Methods of Forming The Same” and filed on Apr. 18, 2023, which claims priority from U.S. Provisional Application Serial No. 63/436,571 entitled “Package Including Composite Interposer and/or Composite Packaging Substrate and Methods of Forming The Same” and filed on Dec. 31, 2022, the entire contents of both of which are incorporated herein by reference for all purposes.

### BACKGROUND

It is desirable for a chip package to provide high computing capabilities without inducing degradation of semiconductor die performance due to generated heat. Chip packages are desired that provide such functionalities in smaller sizes than traditional multi-chip module packages or packages using traditional interposers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first exemplary structure after formation of dielectric liners and metal interconnect structures in a silicon substrate according to various embodiments of the present disclosure.

FIG. 2 is a vertical cross-sectional view of the first exemplary structure after attaching at least one in-interposer semiconductor chip to first bonding structures within the silicon substrate according to various embodiments of the present disclosure.

FIG. 3 is a vertical cross-sectional view of the first exemplary structure after formation of a dielectric matrix according to various embodiments of the present disclosure.

FIG. 4 is a vertical cross-sectional view of the first exemplary structure after polishing materials of the dielectric matrix and the at least one in-interposer semiconductor chip according to the various embodiments of the present disclosure.

FIG. 5 is a vertical cross-sectional view of the first exemplary structure after formation of through-insulator via (TIV) structures according to various embodiments of the present disclosure.

FIG. 6 is vertical cross-sectional view of the first exemplary structure after attaching a first carrier wafer to the at least one in-interposer semiconductor chip and the dielectric matrix according to various embodiments of the present disclosure.

FIG. 7 is vertical cross-sectional view of the first exemplary structure after thinning the silicon substrate according to various embodiments of the present disclosure.

FIG. 8 is a vertical cross-sectional view of the first exemplary structure after formation of bonding structures on the silicon substrate and attaching solder material portions according to various embodiments of the present disclosure.

FIG. 9 is a vertical cross-sectional view of the first exemplary structure after attaching at least one semiconductor die to the silicon substrate and forming an underfill material portion according to various embodiments of the present disclosure.

FIG. 10 is a vertical cross-sectional view of the first exemplary structure after forming a molding compound die frame, attaching a second carrier wafer, and detaching the first carrier wafer according to various embodiments of the present disclosure.

FIG. 11 is a vertical cross-sectional view of the first exemplary structure after formation of an organic redistribution structure and an array of solder material portions according to various embodiments of the present disclosure.

FIG. 12 is a vertical cross-sectional view of the first exemplary structure after attaching an adhesive tape and detaching the second carrier wafer according to various embodiments of the present disclosure.

FIG. 13 is a vertical cross-sectional view of the first exemplary structure after mounting a reconstituted wafer onto a dicing frame, detaching the adhesive tape, and dicing the reconstituted wafer according to various embodiments of the present disclosure.

FIG. 14 is a vertical cross-sectional view of a ceramic layer comprising a set of holes therethrough according to various embodiments of the present disclosure.

FIG. 15 is a vertical cross-sectional view of the ceramic layer after formation of metal interconnects thereupon according to various embodiments of the present disclosure.

FIG. 16 is a vertical cross-sectional view of a set of ceramic layers with metal interconnects thereupon according to various embodiments of the present disclosure.

FIG. 17 is a vertical cross-sectional view of a ceramic core formed by sintering the set of ceramic layers with the metal interconnects according to various embodiments of the present disclosure.

FIG. 18 is a vertical cross-sectional view of an in-process composite packaging substrate after formation of dielectric build-up films according to various embodiments of the present disclosure.

FIG. 19 is a vertical cross-sectional view of the in-process composite packaging substrate after formation of additional metal interconnects according to various embodiments of the present disclosure.

FIG. 20 is a vertical cross-sectional view of an in-process composite packaging substrate after formation of additional dielectric build-up films according to various embodiments of the present disclosure.

FIG. 21 is a vertical cross-sectional view of an in-process composite packaging substrate after formation of bonding pads according to various embodiments of the present disclosure.

FIG. 22 is a vertical cross-sectional view of a composite packaging substrate after formation of passivation dielectric layers according to various embodiments of the present disclosure.

FIG. 23 is a vertical cross-sectional view of the composite packaging substrate after attaching an array of solder material portions according to various embodiments of the present disclosure.

FIG. 24 is a vertical cross-sectional view of a first exemplary chip package structure formed by attaching a first exemplary fan-out package and a stabilization structure to the composite packaging substrate according to various embodiments of the present disclosure.

FIG. 25 is a vertical cross-sectional view of a second exemplary structure after formation of through-insulator via (TIV) structures according to various other embodiments of the present disclosure.

FIG. 26 is vertical cross-sectional view of the second exemplary structure after formation of an organic redistribution structure and an array of solder material portions according to various other embodiments of the present disclosure.

FIG. 27 is a vertical cross-sectional view of the second exemplary structure after attaching at least one semiconductor die to the organic redistribution structure according to various other embodiments of the present disclosure.

FIG. 28 is a vertical cross-sectional view of the second exemplary structure after formation of a molding compound die frame according to various other embodiments of the present disclosure.

FIG. 29 is a vertical cross-sectional view of the second exemplary structure after attaching a first carrier substate to the at least one semiconductor die according to various other embodiments of the present disclosure.

FIG. 30 is vertical cross-sectional view of the second exemplary structure after thinning the silicon substrate according to various other embodiments of the present disclosure.

FIG. 31 is a vertical cross-sectional view of the second exemplary structure after formation of bonding structures on the silicon substrate and attaching solder material portions according to various other embodiments of the present disclosure.

FIG. 32 is a vertical cross-sectional view of the second exemplary structure after attaching an adhesive tape to the solder material portions and detaching the first carrier wafer according to various other embodiments of the present disclosure.

FIG. 33 is a vertical cross-sectional view of the second exemplary structure after mounting a reconstituted wafer onto a dicing frame, detaching the adhesive tape, and dicing the reconstituted wafer according to various other embodiments of the present disclosure.

FIG. 34 is a vertical cross-sectional view of a second exemplary chip package structure formed by attaching a second exemplary fan-out package and a stabilization structure to a composite packaging substrate according to various other embodiments of the present disclosure.

FIG. 35 is a vertical cross-sectional view of a third exemplary chip package structure according to various other embodiments of the present disclosure.

FIG. 36 is a vertical cross-sectional view of a fourth exemplary chip package structure according to various other embodiments of the present disclosure.

FIG. 37 is a first flowchart illustrating steps for forming a chip package structure according to various embodiments of the present disclosure.

FIG. 38 is a second flowchart illustrating steps for forming a chip package structure according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity, and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Multi-chip module (MCM) packages or multi-chip modules using a large interposer manufactured using two or more reticles are typically used to provide high performance computing chip package structures. However, such MCM packages or multi-chip modules with large interposers suffer from degradation in the computing speed due to long signal transmission paths in the large interposers and heat accumulation at a substrate core. Further, very large sizes of such chip package structures make it difficult to mount the chip package structures on a motherboard or in a high performance computing (HPC) system.

Various embodiments disclosed herein are directed to semiconductor devices, and particularly to chip package structures including a composite interposer containing at least one in-interposer semiconductor chip including a respective semiconductor circuitry therein, a dielectric matrix laterally surrounding the at least one in-interposer semiconductor chip, a die-side redistribution structure located on a first side of the dielectric matrix, and a substrate-side redistribution structure located on a second side of the dielectric matrix. At least one of the die-side redistribution structure and the substrate-side redistribution structure may comprise a silicon interposer. The at least one in-interposer semiconductor chip may be a hybrid bonding chip such as an input/output control chip, a system-on-chip (SoC) chip, a static random access memory (SRAM) chip, or a dynamic random access memory (DRAM) chip.

In one embodiment, a composite packaging substrate may be bonded to the composite interposer. The composite packaging substrate comprises: at least one ceramic layer comprising a respective set of holes therethrough; front-side dielectric build-up films located on a front side of the at least one ceramic layer; backside dielectric build-up films located on a backside of the at least one ceramic layer; and metal interconnects providing electrical connection from a front side of the front-side dielectric build-up films to a backside of the backside dielectric build-up films. Generally, the composite packaging substrate of embodiments of the present disclosure functions as an advanced packaging substrate that includes as least one ceramic layer that increases heat dissipation capacity of the packaging substrate. Various aspects of embodiments of the present disclosure are now described with reference to accompanying figures.

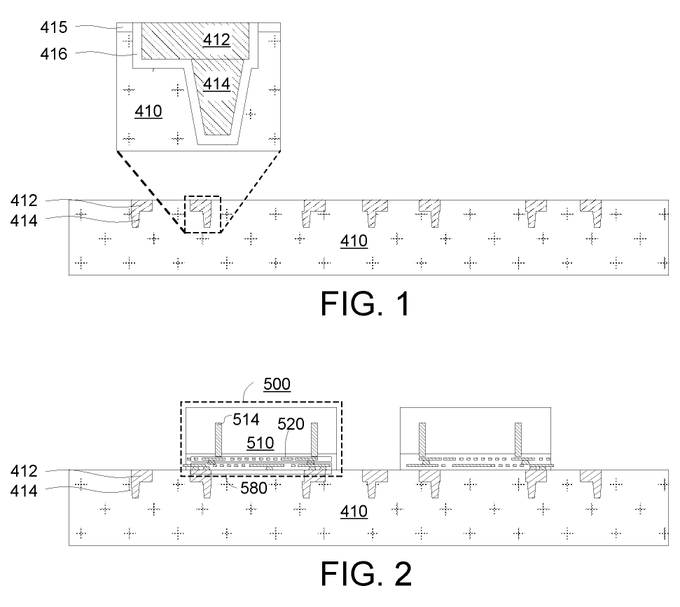

Referring to FIG. 1, a first exemplary structure according to a first embodiment of the present disclosure is illustrated with an inset that shows a magnified view of a region. The first exemplary structure comprises a silicon substrate 410, which may comprise a commercially available silicon wafer. A planar dielectric layer 415 such as a silicon oxide layer may be optionally formed on a top surface of the silicon substrate 410, for example, by thermal oxidation. Cavities may be formed in an upper portion of the silicon substrate 410 using a combination of lithographic patterning methods and at least one anisotropic etch process. For example, the cavities may comprise integrated line and via cavities and/or integrated pad and via cavities, within each of which at least one via cavity is connected to a line cavity or a pad cavity. A dielectric liner 416 may be formed within each of the cavities, and a metallic material may be deposited in remaining volumes of the cavities to form metal interconnect structures (412, 414). The metal interconnect structures (412, 414) may comprise first bonding structures 412 having pad shapes and located on a first side of the silicon substrate 410, and via structures which are herein referred to as through-silicon via (TSV) structures 414. Generally, the metal interconnect structures (412, 414) are formed within the silicon substrate 410 and are electrically isolated from the silicon substrate 410 by the dielectric liners 416. The total vertical extent of the metal interconnect structures (412, 414) may be in a range from 5 microns to 20 microns, and the thickness of the silicon substrate 410 may be in a range from 300 microns to 1 mm.

While the illustrated portion of the first exemplary structure illustrated in FIG. 1 and subsequent drawings corresponds to an area of a single interposer to be subsequently formed, it is understood that a two-dimensional array of interposers may be simultaneously formed on a same silicon substrate 410 and may be subsequently diced to form a plurality of discrete interposers. As such, the drawings of the present disclosure that correspond to processing steps prior to dicing of the silicon substrate 410 are to be construed as representations of a single interposer area within a larger structure in which multiple units of the illustrated structure are repeated in a two-dimensional array.

Referring to FIG. 2, at least one semiconductor chip may be attached to first bonding structures 412 that are formed within the silicon substrate 410. Each semiconductor chip that is attached to the silicon substrate 410 is subsequently incorporated within an interposer, and as such, is herein referred to as an in-interposer semiconductor chip 500. Each in-interposer semiconductor chip 500 may comprise a respective semiconductor substrate 510 embedding respective through-substrate via structures 514 therein. According to an aspect of the present disclosure, the at least one in-interposer semiconductor chip 500 may include a respective semiconductor circuitry (520, 580) located on the respective semiconductor substrate 510. Each semiconductor circuitry (520, 580) comprises semiconductor devices 520 such as complementary metal-oxide-semiconductor (CMOS) devices including field effect transistors, and metal interconnect structures 580 that may be formed within interlayer dielectric (ILD) layers. The ILD layers may be dielectric material layers that embed the metal interconnect structures 580. A subset of the metal interconnect structures 580 may comprise a set of metallic bonding structures, which is herein referred to as a set of chip-side bonding structures.

The at least one in-interposer semiconductor chip 500 may comprise an active functional semiconductor chip, which may be, for example, an input/output control chip, a system-on-chip (SoC) chip, a static random access memory (SRAM) chip, or a dynamic random access memory (DRAM) chip. The at least one in-interposer semiconductor chip 500 may comprise a plurality of in-interposer semiconductor chips 500. One, a plurality, and/or each, of the at least one in-interposer semiconductor chip 500 may be a high bandwidth semiconductor chip that may transmit electrical signals at a high frequency. In one embodiment, one, a plurality, and/or each, of the at least one in-interposer semiconductor chip 500 may have a respective set of chip-side bonding structures that are bonded to the first bonding structures 412 in the silicon substrate 410 through metal-to-metal bonding. Further, a bottommost layer selected from the ILD layers within one, a plurality, and/or each, of the at least one in-interposer semiconductor chip 500 may be bonded to the planar dielectric layer 415 located on the silicon substrate 410 via dielectric-to-dielectric bonding such as oxide-to-oxide bonding (e.g., silicon oxide-to-silicon oxide bonding). In this embodiment, one, a plurality, and/or each, of the at least one in-interposer semiconductor chip 500 may be bonded to the combination of the silicon substrate 410, the planar dielectric layer 415, and the metal interconnect structures (412, 414) via hybrid bonding (e.g., metal-to-metal and dielectric-to-dielectric bonding).

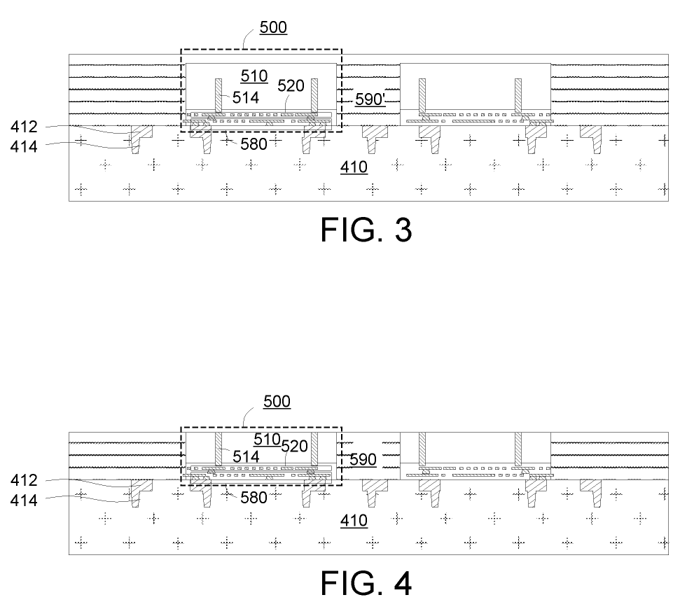

Referring to FIG. 3, a dielectric fill material portion 590’ may be formed around the at least one in-interposer semiconductor chip 500 by depositing a dielectric fill material. The dielectric fill material may be deposited by a conformal deposition process (such as a chemical vapor deposition process) or by a self-planarizing deposition process (such as a spin-coating process). The dielectric fill material may comprise, for example, undoped silicate glass, a doped silicate glass, spin-on-glass (such as flowable oxide (FOx)), or another silicon-oxide based material.

Referring to FIG. 4, portions of the dielectric fill material and each upper portion of the at least one in-interposer semiconductor chip 500 that are distal from the silicon substrate 410 may be removed by performing a planarization process. For example, grinding, polishing, an anisotropic etch process, and/or an isotropic etch process may be performed to remove portions of the dielectric fill material and each upper portion of the at least one in-interposer semiconductor chip 500 that are more distal from the silicon substrate 410 than topmost surfaces of the through-substrate via structures 514 within the at least one in-interposer semiconductor chip 500. A remaining portion of the dielectric fill material after the planarization process comprises the dielectric matrix 590. Each of the at least one in-interposer semiconductor chip 500 may be thinned such that backside end surfaces of the through-substrate via structures 514 are physically exposed. In one embodiment, the physically exposed backside surfaces of the at least one in-interposer semiconductor chip 500 may be formed within a horizontal plane including the physically exposed horizontal surface of the dielectric matrix 590. Generally, the dielectric matrix 590 is formed around, and laterally surrounds each of, the at least one in-interposer semiconductor chip 500. The first exemplary structure comprises a reconstituted wafer in which at least one in-interposer semiconductor chip 500 is bonded to the silicon substrate 410 within each unit area (i.e., an area that corresponds to an area of a composite interposer to be subsequently formed).

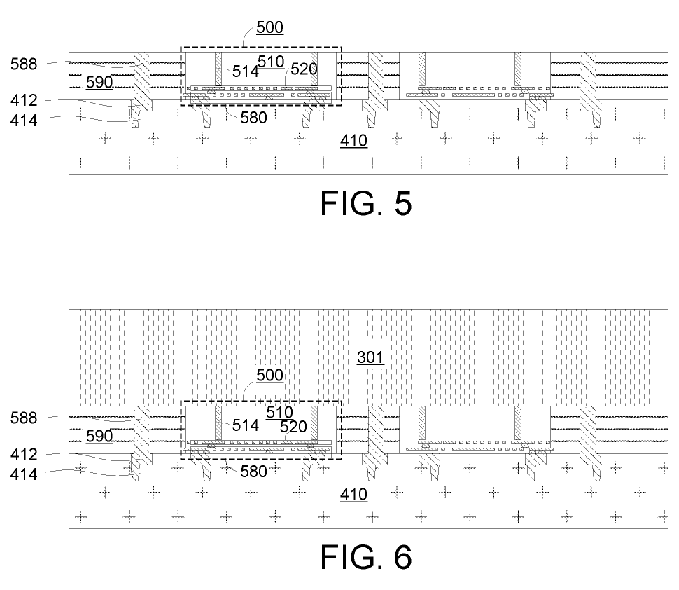

Referring to FIG. 5, a photoresist layer (not shown) may be applied over the dielectric matrix 590 and the in-interposer semiconductor chips 500, and may be lithographically patterned to form openings within areas of the dielectric matrix 590 that overlie a respective one of the first bonding structures 412 within the silicon substrate 410. An anisotropic etch process may be performed to form via cavities through the dielectric matrix 590, which are herein referred to as through-insulator via cavities. The photoresist layer may be subsequently removed, for example, by ashing. At least one conductive material, such as at least one metallic material, may be deposited in the through-insulator via cavities, for example, by physical vapor deposition, chemical vapor deposition, and/or electroplating. Excess portions of the at least one conductive material may be removed from above the horizontal plane including the top surface of the dielectric matrix 590 by a planarization process such as a recess etch process or a chemical mechanical polishing (CMP) process. Remaining portions of the at least one conductive material constitute through-insulator via (TIV) structures 588 that contact a top surface of a respective one of the first bonding structures 412, which are a subset of the metal interconnect structures (412, 414) in the silicon substrate 410.

Referring to FIG. 6, a first carrier wafer 301 may be attached to the at least one in-interposer semiconductor chip 500 and the dielectric matrix 590. For example, an adhesive layer (not shown) may be formed on the physically exposed surfaces of the dielectric matric 590 and the in-interposer semiconductor dies 500, and the first carrier wafer 301 may be attached to the adhesive layer. The first carrier wafer 301 may comprise a dielectric substrate (such as a glass substrate), a semiconductor substrate, or a conductive substrate.

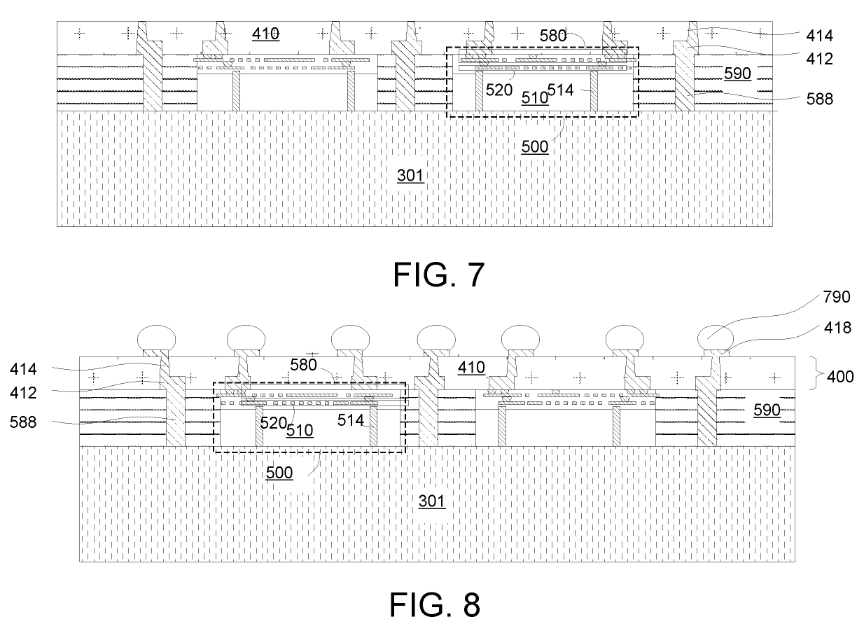

Referring to FIG. 7, the silicon substrate 410 may be thinned the silicon substrate 410 by removing a portion of the silicon substrate 410 from a second side (i.e., the backside or the physically exposed side) of the silicon substrate 410. The silicon substrate 410 may be thinned, for example, by grinding, polishing, an anisotropic etch process, and/or an isotropic etch process. A subset of the metal interconnect structures (412, 414) may be physically exposed upon removal of the backside portion of the silicon substrate 410. Specifically, end surfaces of the through-silicon via structures 414 may be physically exposed upon thinning of the silicon substrate 410.

The combination of the silicon substrate 410, the optional planar dielectric layer 415, the dielectric liners 416, and the metal interconnect structures (412, 414) embedded within the silicon substrate 410 constitutes a silicon interposer 400. The at least one in-interposer semiconductor chip 500 comprises chip-side bonding structures that are bonded to the first bonding structures 412 of the silicon interposer 400 through metal-to-metal bonding.

Referring to FIG. 8, backside bonding structures 418 may be optionally formed on the physically exposed end surfaces of the through-silicon via structures 414. In one embodiment, the backside bonding structures 418 may comprise copper pads or copper pillar structures. Generally, metallic bonding structures may be provided, which may comprise the backside bonding structures 418 or the through-silicon via structures 414. The metallic bonding structures (418 or 414) are also referred to as second bonding structures. Solder material portions may be attached to the metallic bonding structures (418 or 414). The solder material portions are used to provide electrical connection between a composite interposer to be subsequently formed and semiconductor dies to be subsequently attached to the composite interposer and are herein referred to as die-interposer (DI) solder material potions 790.

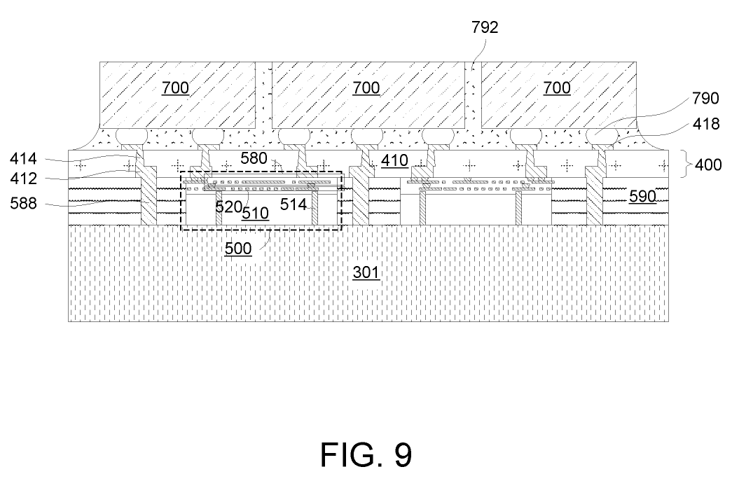

Referring to FIG. 9, at least one semiconductor die 700 may be attached to the silicon interposer 400 including the silicon substrate 410. Specifically, the at least one semiconductor die 700 may be bonded to second bonding structures (414, 418) located on a second side of the silicon substrate 410 through a respective array of DI solder material portions 790. Generally, the silicon interposer 400 comprises second bonding structures (414 or 418) (which are metallic bonding structures) that are located on the second side of the silicon substrate 410 and face the at least one semiconductor die 700, and the at least one semiconductor die 700 may be attached to the second bonding structures (414 or 418) through a respective array of DI solder material portions 790. As discussed above, the second bonding structures may comprise a subset of the metal interconnect structures (412, 414) (such as the through-silicon via structures 414) or may comprise backside bonding structures 418 that are formed on the subset of the metal interconnect structures (412, 414) after the subset of the metal interconnect structures (412, 414) is physically exposed. An underfill material portion 792 may be formed around the array(s) of DI solder material portions 790. In embodiments in which the at least one semiconductor die 700 comprises a plurality of semiconductor dies 700, the underfill material portion 792 may fill the gap(s) between each neighboring pair of semiconductor dies 700.

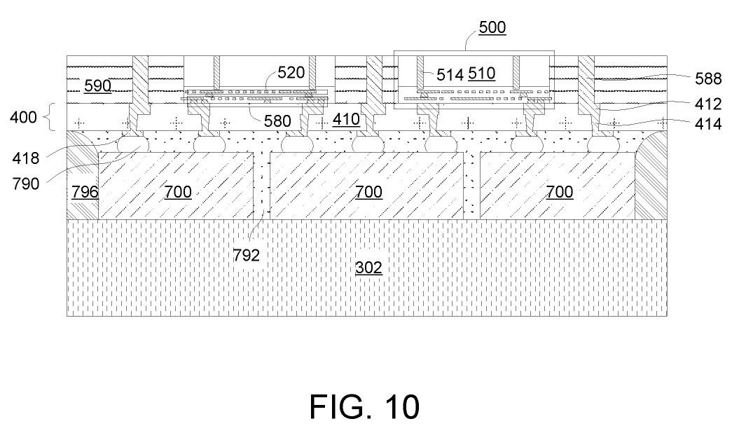

Referring to FIG. 10, an encapsulant, such as a molding compound (MC) may be applied around each contiguous combination of at least one semiconductor die 700 and an underfill material portion 792. The MC includes an epoxy-containing compound that may be hardened (i.e., cured) to provide a dielectric material portion having sufficient stiffness and mechanical strength. The MC may include epoxy resin, hardener, silica (as a filler material), and other additives. The MC may be provided in a liquid form or in a solid form depending on the viscosity and flowability. Liquid MC typically provides better handling, good flowability, less voids, better fill, and less flow marks. Solid MC typically provides less cure shrinkage, better stand-off, and less die drift. A high filler content (such as 85% in weight) within an MC may shorten the time in mold, lower the mold shrinkage, and reduce the mold warpage. Uniform filler size distribution in the MC may reduce flow marks, and may enhance flowability.

The MC may be cured at a curing temperature to form a molding compound (MC) matrix. The MC matrix may continuously extend over a two-dimensional array of unit areas in the reconstituted wafer. Excess portions of the MC matrix may be removed from above the horizontal plane including the top surfaces of the semiconductor dies 700 by a planarization process, which may use chemical mechanical planarization (CMP). In one embodiment, top portions of a subset of the semiconductor dies 700 may be removed so that top surfaces of the semiconductor dies 700 are located within a horizontal plane including the top surface of the MC matrix. Each portion of the MC matrix that is located within a respective unit area constitutes a molding compound (MC) die frame 796.

A second carrier wafer 302 may be attached to the semiconductor dies 700 and the MC die frames 796. For example, an adhesive layer (not shown) may be applied to the physically exposed surfaces of the semiconductor dies 700 and the MC matrix, and the second carrier wafer 302 may be attached to the adhesive layer. Subsequently, the first carrier wafer 301 may be detached from the dielectric matrix 590 and the in-interposer semiconductor chips 500. Any remaining portion of an adhesive material may be cleaned from surfaces of the dielectric matrix 590 and the in-interposer semiconductor chips 500.

Generally, a molding compound die frame 796 may be formed around the at least one semiconductor die 700 within each unit area. A second carrier wafer 302 may be attached to the at least one semiconductor die 700 and the molding compound die frame 796, and the first carrier wafer 301 may be detached from the at least one in-interposer semiconductor chip 500 and the dielectric matrix 590.

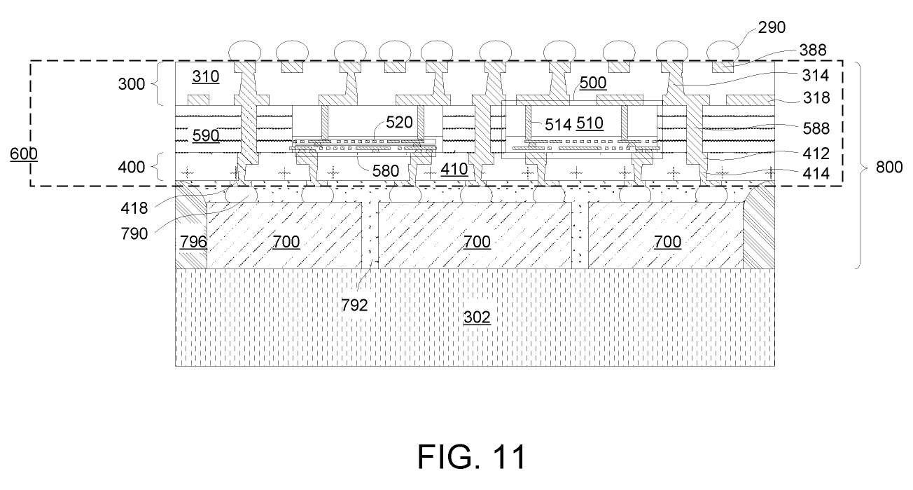

Referring to FIG. 11, an organic redistribution structure 300 may be formed on the dielectric matrix 590 and the in-interposer semiconductor chips 500. The organic redistribution structure 300 may include polymer-based insulating layers 310 and metal interconnects (314, 318, 388). The polymer-based insulating layers 310 are also referred to as redistribution dielectric layers and include a respective dielectric polymer material such as polyimide (PI), benzocyclobutene (BCB), or polybenzobisoxazole (PBO). Each of the polymer-based insulating layers 310 may be formed by spin coating and drying of the respective dielectric polymer material. The thickness of each polymer-based insulating layer 310 may be in a range from 2 microns to 40 microns, such as from 4 microns to 20 microns. Each polymer-based insulating layer 310 may be patterned, for example, by applying and patterning a respective photoresist layer thereabove, and by transferring the pattern in the photoresist layer into the polymer-based insulating layer 310 using an etch process such as an anisotropic etch process. The photoresist layer may be subsequently removed, for example, by ashing.

Each of the metal interconnects (314, 318, 388) may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 300 nm, and the copper seed layer may have a thickness in a range from 100 nm to 500 nm. The metallic fill material for the metal interconnects (314, 318, 388) may include copper, nickel, or copper and nickel. The thickness of the metallic fill material that is deposited for each metal interconnects (314, 318, 388) may be in a range from 2 microns to 40 microns, such as from 4 microns to 10 microns, although lesser or greater thicknesses may also be used. The total number of levels of wiring in the organic redistribution structure 300 may be in a range from 1 to 10. The metal interconnects (314, 318, 388) may comprise metal line structures 318, metal via structures 314, and metallic bonding structures 388.

The through insulator via (TIV) structures 588 extend through the dielectric matrix 590, and connect a respective pair of metal interconnect structures (412, 318) in the silicon interposer 400 and in the organic redistribution structure 300, respectively. A composite interposer 600 is provided, which comprises at least one in-interposer semiconductor chip 500 including a respective semiconductor circuitry (520, 580) therein, a dielectric matrix 590 laterally surrounding the at least one in-interposer semiconductor chip 500, a die-side redistribution structure comprising a silicon interposer 400 and located on a first side of the dielectric matrix 590, and a substrate-side redistribution structure comprising an organic redistribution structure 300 located on a second side of the dielectric matrix 590. At least one semiconductor die 700 may be attached to the die-side redistribution structure (400 or 300) through a respective array of solder material portions 790. In one embodiment, the silicon interposer 400 comprises metallic bonding structures (such as first bonding structures 414) facing the at least one semiconductor die 700; and each semiconductor die 700 is bonded to a respective array of solder material portions 790, which is bonded to a respective subset of the metallic bonding structures (414 or 418).

While the present disclosure is described using an embodiment in which the at least one semiconductor die 700 is bonded to the silicon interposer 400 prior to formation of an organic redistribution structure 300, embodiments are expressly contemplated herein in which formation of the organic redistribution structure 300 precedes attachment of the at least one semiconductor die 700 to the silicon interposer 400. For example, the organic redistribution structure 300 may be formed on the first exemplary structure illustrated in FIG. 5, and the first carrier substrate 301 may be attached to the organic redistribution structure 300 so that formation of the organic redistribution structure 300 precedes formation of a silicon interposer 400 and attachment of the at least one semiconductor die 700 to the silicon interposer 400.

The combination of the composite interposer 600, at least one semiconductor die 700, and the molding compound matrix 796 located within each unit area in the reconstituted wafer constitutes a fan-out package 800. An array of solder material portions may be attached to the metallic bonding structures 388 in the organic interposer structure 300. The array of IS solder material portions may be subsequently used to provide electrical connection between the composite interposer 600 and a packaging substrate and is herein referred to as an array of interposer-substrate (IS) solder material portions 290.

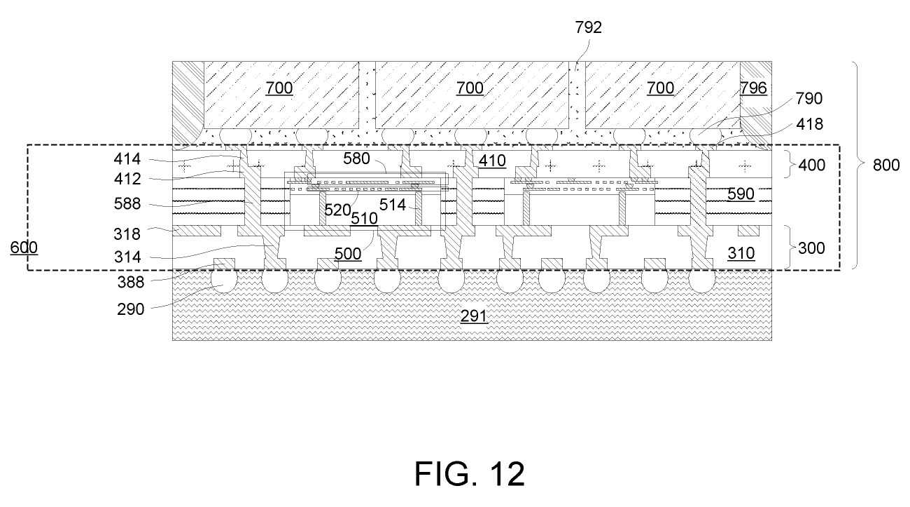

Referring to FIG. 12, an adhesive tape 291 may be attached to the array of IS solder material potions 290. The second carrier wafer 302 may be subsequently detached, and a suitable cleaning process may be performed to remove residual portions of the adhesive material from the physically exposed surfaces of the semiconductor dies 700 and the MC matrix that includes a two-dimensional array of MC die frames 796.

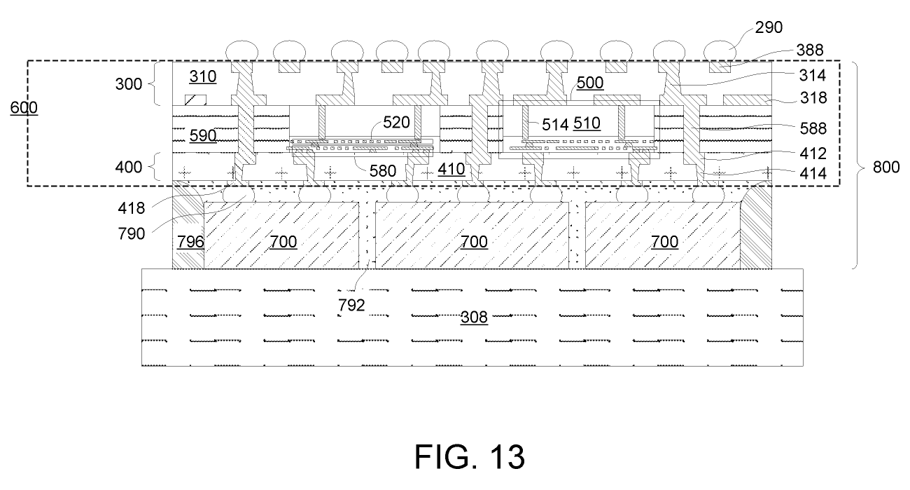

Referring to FIG. 13, the reconstituted wafer including a two-dimensional array of fan-out packages 800 may be mounted onto a dicing frame 308. The adhesive tape 291 may be subsequently removed. The reconstituted wafer may be diced along dicing channels so that the fan-out packages 800 are singulated into discrete structures. The diced fan-out packages 800 may be subsequently detached from the dicing frame 308.

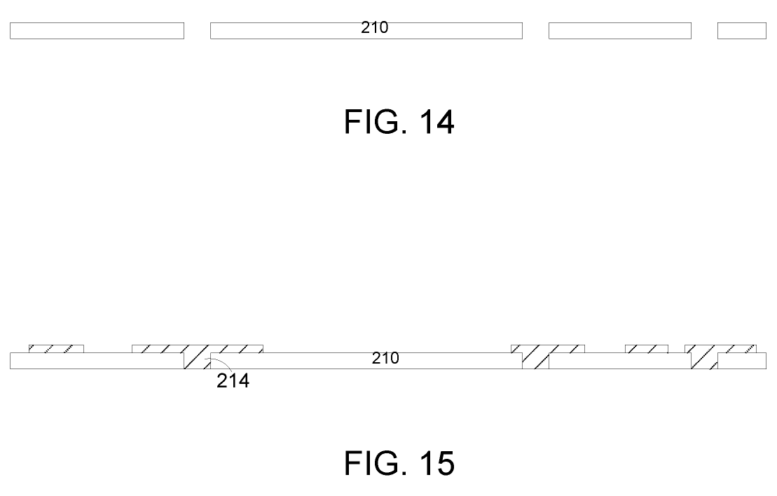

Referring to FIG. 14, a ceramic layer 210 comprising a set of holes therethrough is illustrated, which may be subsequently used to form a composite packaging substrate according to an embodiment of the present disclosure. The ceramic layer 210 includes a ceramic material, which is a dielectric material having a thermal conductivity greater than 2 W/m⋅K. Generally, polymer materials used in organic interposers have a thermal conductively that is less than 0.4 W/m⋅K. The ceramic layer 210 may have a thickness in a range from 5 microns to 60 microns, such as from 10 microns to 30 microns, although lesser and greater thicknesses may also be used.

Referring to FIG. 15, metal interconnects 214 may be formed on the ceramic layer 210. The metal interconnects 214 may be formed by depositing and patterning at least one metallic material such as a metallic liner material and a metallic plating material.

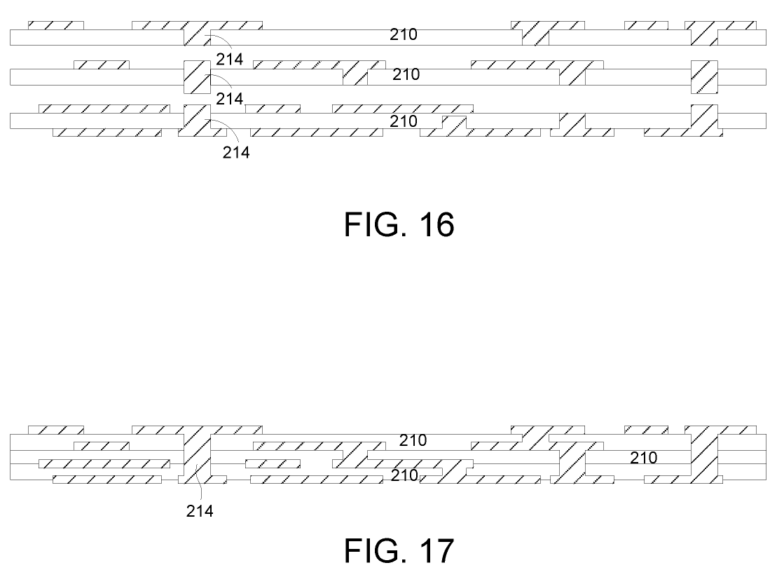

Referring to FIG. 16, a set of ceramic layers 210 with metal interconnects 214 thereupon is illustrated. The pattern of the metal interconnects 214 on the ceramic layers 210 may be selected such that an assembly of the set of ceramic layers 210 and the metal interconnects 214 may provide electrical connections through a layer stack of the ceramic layers 210.

Referring to FIG. 17, the set of ceramic layers 210 with metal interconnects 214 thereupon are assembled as a contiguous structure, and may be sintered to form a ceramic-based core structure (210, 214) of a composite packaging substrate to be subsequently formed. While three ceramic layers 210 are illustrated within the ceramic-based core structure (210, 214) illustrated in FIG. 17, the total number of the ceramic layers 210 within the ceramic-based core structure (210, 214) may be in a range from 1 to 20.

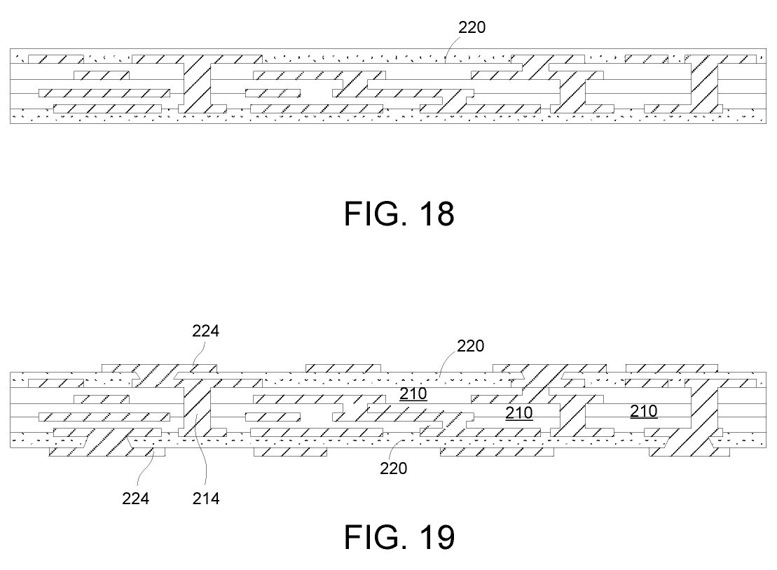

Referring to FIG. 18, dielectric build-up films 220 may be formed on both sides of the ceramic-based core structure (210, 214). For example, the dielectric build-up films 220 may comprise one or more Ajinomoto Build-up Film (ABF). The combination of the ceramic-based core structure (210, 214) and the dielectric build-up films 220 constitute an in-process composite packaging substrate, i.e., a structure that is subsequently modified to form a composite packaging substrate.

Referring to FIG. 19, the dielectric build-up films 220 may be patterned, and additional metal interconnects 224 may be formed.

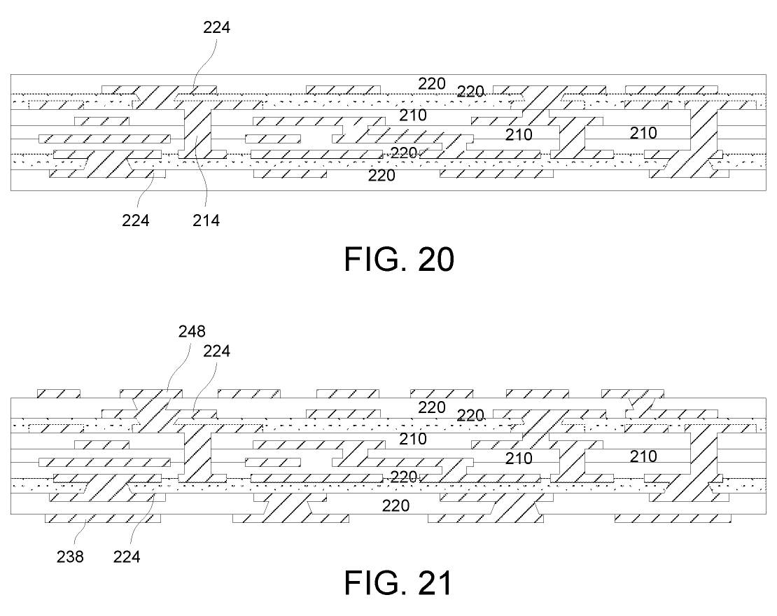

Referring to FIG. 20, additional dielectric build-up films 220 may be formed on the in-process composite packaging substrate.

Generally, the processing seps of FIGS. 19 and 20 may be repeated as many times as needed which necessary changes in the pattern of the metal interconnects 224 to increase the wiring levels on the in-process composite packaging substrate.

Referring to FIG. 21, outermost dielectric build-up films 220 may be patterned, and substrate bonding pads (238, 248) may be formed by deposition and patterning of at least one metallic material. The substrate bonding pads (238, 248) may comprise first substrate bonding pads 238 that are formed on a first side of the in-process composite packaging substrate, and second substrate bonding pads 248 that are formed on a second side of the in-process composite packaging substrate.

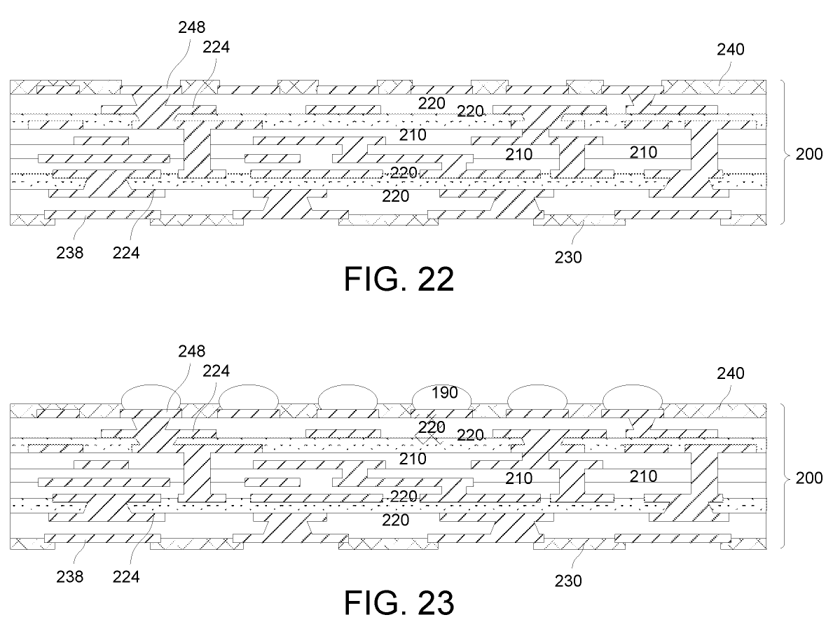

Referring to FIG. 22, passivation dielectric layers (230, 240) may be formed over the substrate bonding pads (238, 248) and the outermost dielectric build-up films 220 and may be patterned to form openings over areas of the substrate bonding pads (238, 248). A composite packaging substrate 200 may be provided. The passivation dielectric layers (230, 240) may comprise a first passivation dielectric layer 230 formed on the first side of the composite packaging substrate 200, and a second passivation dielectric layer 240 formed on the second side of the composite packaging substrate 200. The composite packaging substrate 200 of embodiments of the present disclosure provides superior thermal conduction at the ceramic-based core structure (210, 214) due to the higher thermal conductivity of the ceramic layers 210 relative to polymer-based packaging substrates. Thus, when used in combination with the composite interposer 600 of embodiments of the present disclosure, the composite packaging substrate 200 may provide superior thermal dissipation in a chip package structure.

Generally, the composite packaging substrate 200 comprises at least one ceramic layer 210 comprising a respective set of holes therethrough; first dielectric build-up films 220 located on a first side of the at least one ceramic layer 210; second dielectric build-up films 220 located on a second side of the at least one ceramic layer 210; and metal interconnects (214, 224) providing electrical connection through the first dielectric build-up films 220, the at least one ceramic layer 210, and the second dielectric build-up films 220.

Referring to FIG. 23, an array of solder material portions may be attached to the second substrate bonding pads 248. The array of solder material portions 190 is subsequently used to provide electrical connection between the composite packaging substrate 200 and a printed circuit board, and is herein referred to as an array of substrate-board (SB) solder material portions.

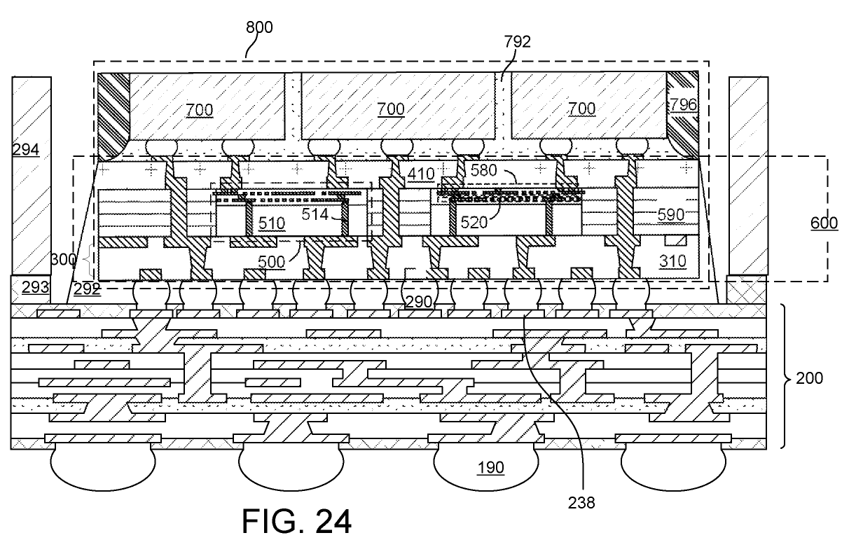

Referring to FIG. 24, the fan-out package 800 including composite interposer 600, the at least one semiconductor die 700, and the MC die frame 796 illustrated in FIG. 13 may be attached to the composite packaging substrate 200 illustrated in FIG. 23. The array of IS solder material portions 290 may be aligned to the array of first substrate bonding pads 238, and a reflow process may be performed to induce bonding between the array of IS solder material portions 290 and the array of first substrate bonding pads 238. Generally, an assembly comprising the at least one in-interposer semiconductor chip 500, the dielectric matrix 590, the organic redistribution structure 300, and the at least one semiconductor die 700 may be attached to the composite packaging substrate 200. A stabilization structure 294 such as a stabilization ring or a stabilization lid may be attached to the composite packaging substrate 200 using an adhesive layer 293 and/or a thermal interface layer (not shown).

Subsequently, the assembly of the fan-out package 800 and the composite interposer 200 may be attached to a printed circuit board (not shown) using the array of SB solder material portions 190.

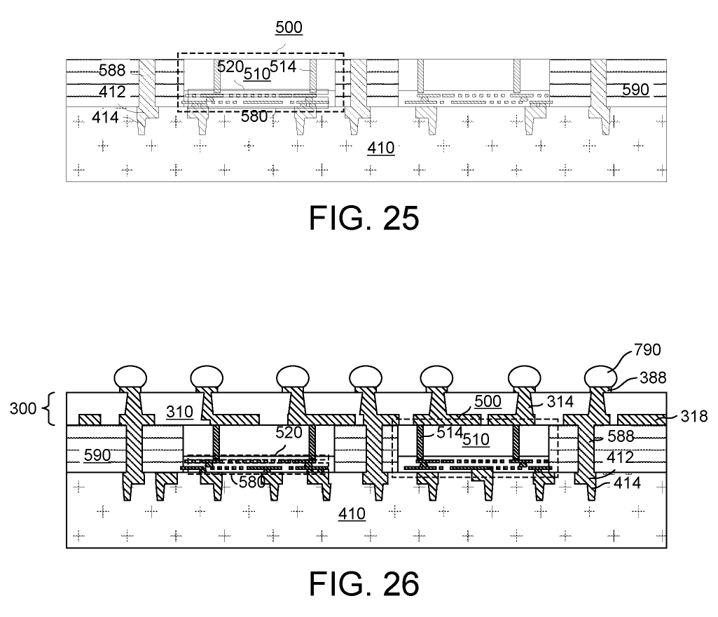

Referring to FIG. 25, an exemplary structure according to various embodiments of the present disclosure may be the same as the first exemplary structure illustrated in FIG. 5.

Referring to FIG. 26, the processing steps of FIG. 11 may be performed to form an organic redistribution structure 300 on the dielectric matrix 590 and the in-interposer semiconductor chips 500. The organic redistribution structure 300 includes polymer-based insulating layers 301 and metal interconnects (314, 318, 388) as described above. The through insulator via (TIV) structures 588 extend through the dielectric matrix 590 and connect a respective pair of metal interconnect structures (412, 318) in the silicon substrate 410 and in the organic redistribution structure 300. The organic redistribution structure 300 constitutes a die-side redistribution structure that is subsequently used to attach at least one semiconductor die. The metal interconnects (314, 318, 388) may comprise metal line structures 318, metal via structures 314, and metallic bonding structures 388.

Solder material portions may be attached to the metallic bonding structures 388. The solder material portions are used to provide electrical connection between a composite interposer to be subsequently formed and semiconductor dies to be subsequently attached to the composite interposer and are herein referred to as die-interposer (DI) solder material potions 790.

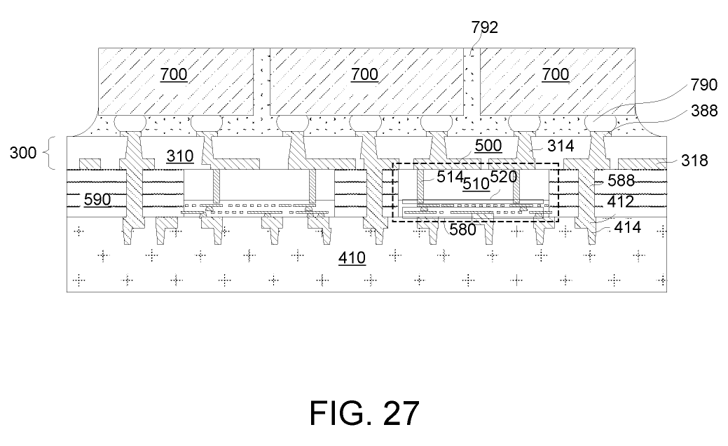

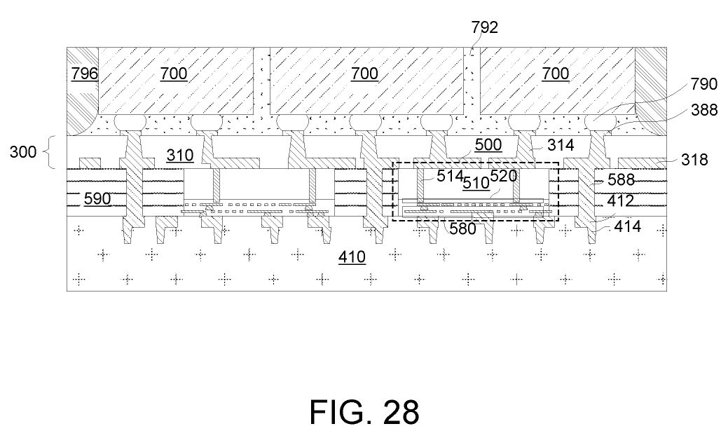

Referring to FIG. 27, at least one semiconductor die 700 may be attached to the organic redistribution structure 300. Specifically, the at least one semiconductor die 700 may be bonded to metallic bonding structures 388 located on the organic redistribution structure 300 through a respective array of DI solder material portions 790. Generally, the organic redistribution structure 300 comprises metallic bonding structures 388 facing the at least one semiconductor die 700, and the at least one semiconductor die 700 may be attached to the metallic bonding structures 388 through a respective array of DI solder material portions 790. An underfill material portion 792 may be formed around the array(s) of DI solder material portions 790. In embodiments in which the at least one semiconductor die 700 comprises a plurality of semiconductor dies 700, the underfill material portion 792 may fill the gap(s) between each neighboring pair of semiconductor dies 700.

While the present disclosure is described using an embodiment in which the at least one semiconductor die 700 is bonded to the organic redistribution structure 300 prior to thinning the silicon substrate 410, embodiments are expressly contemplated herein in which thinning of the silicon substrate 410 and formation of a silicon interposer precedes attachment of the at least one semiconductor die 700 to the organic redistribution structure 300. In this embodiment, a carrier substrate (not shown) may be used to thin the backside of the silicon substrate 410 and to provide a silicon interposer prior to attaching the at least one semiconductor die 700 to the organic redistribution structure 300.

Referring to FIG. 28, an encapsulant, such as a molding compound (MC) may be applied around each contiguous combination of at least one semiconductor die 700 and an underfill material portion 792. The MC may comprise a same material as the MC used in the first exemplary structure. The MC may be cured at a curing temperature to form a molding compound (MC) matrix. The MC matrix may continuously extend over a two-dimensional array of unit areas in the reconstituted wafer. Excess portions of the MC matrix may be removed from above the horizontal plane including the top surfaces of the semiconductor dies 700 by a planarization process, which may use chemical mechanical planarization (CMP). In one embodiment, top portions of a subset of the semiconductor dies 700 may be removed so that top surfaces of the semiconductor dies 700 are located within a horizontal plane including the top surface of the MC matrix. Each portion of the MC matrix that is located within a respective unit area constitutes a molding compound (MC) die frame 796.

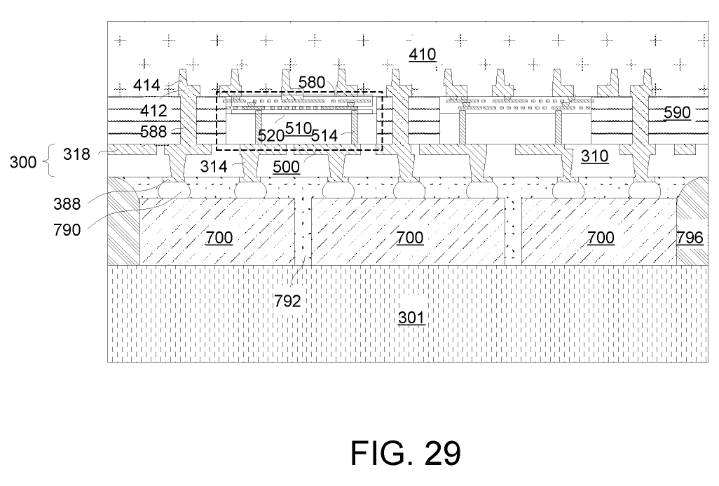

Referring to FIG. 29, a first carrier wafer 301 may be attached to the semiconductor dies 700 and the MC die frames 796. For example, an adhesive layer (not shown) may be applied to the physically exposed surfaces of the semiconductor dies 700 and the MC matrix, and the first carrier wafer 301 may be attached to the adhesive layer.

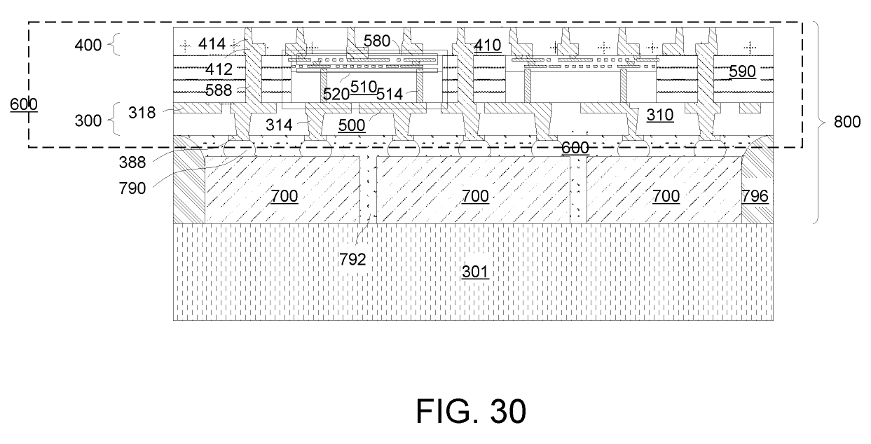

Referring to FIG. 30, the silicon substrate 410 may be thinned by removing a portion of the silicon substrate 410 from a second side (i.e., the backside or the physically exposed side) of the silicon substrate 410. The silicon substrate 410 may be thinned, for example, by grinding, polishing, an anisotropic etch process, and/or an isotropic etch process. A subset of the metal interconnect structures (412, 414) may be physically exposed upon removal of the backside portion of the silicon substrate 410. Specifically, end surfaces of the through-silicon via structures 414 may be physically exposed upon thinning of the silicon substrate 410.

The combination of the silicon substrate 410, the optional planar dielectric layer 415, the dielectric liners 416, and the metal interconnect structures (412, 414) embedded within the silicon substrate 410 constitutes a silicon interposer 400. The at least one in-interposer semiconductor chip 500 comprises chip-side bonding structures that are bonded to the first bonding structures 412 of the silicon interposer 400 through metal-to-metal bonding. The through insulator via (TIV) structures 588 extend through the dielectric matrix 590 and connect a respective pair of metal interconnect structures (412, 318) in the silicon interposer 400 and in the organic redistribution structure 300.

A composite interposer 600 is provided, which comprises at least one in-interposer semiconductor chip 500 including a respective semiconductor circuitry (520, 580) therein, a dielectric matrix 590 laterally surrounding the at least one in-interposer semiconductor chip 500, a die-side redistribution structure comprising an organic redistribution structure 300 and located on a first side of the dielectric matrix 590, and a substrate-side redistribution structure comprising a silicon interposer 400 located on a second side of the dielectric matrix 590. At least one semiconductor dies 700 is attached to the die-side redistribution structure (400 or 300) through a respective array of solder material portions 790. In one embodiment, the organic redistribution structure 300 comprises metallic bonding structures 388 facing the at least one semiconductor dies 700; and each semiconductor die 700 is bonded to a respective array of solder material portions 790, which is bonded to a respective subset of the metallic bonding structures 388. The combination of the composite interposer 600, at least one semiconductor die 700, and the molding compound matrix 796 located within each unit area in the reconstituted wafer constitutes a fan-out package 800.

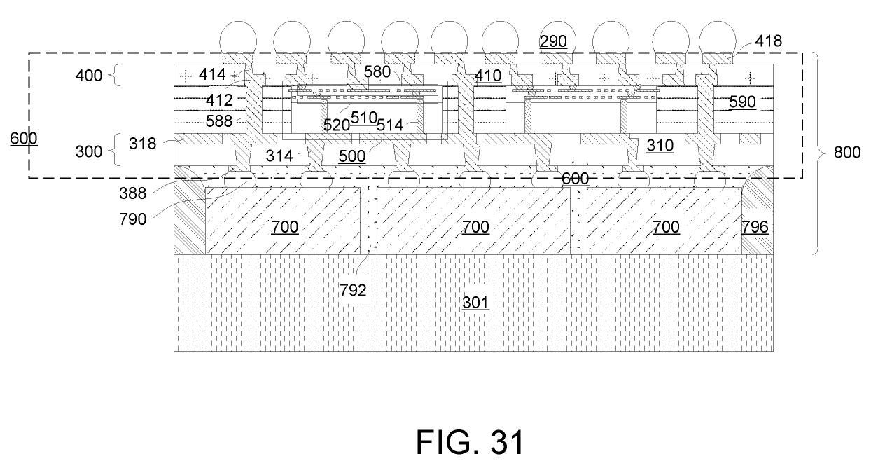

Referring to FIG. 31, backside bonding structures 418 may be optionally formed on the physically exposed end surfaces of the through-silicon via structures 414. In one embodiment, the backside bonding structures 418 may comprise copper pads. The backside bonding structures 418 are incorporated into the silicon interposer 400. Generally, metallic bonding structures may be provided, which may comprise the backside bonding structures 418 or the through-silicon via structures 414. The metallic bonding structures (418 or 414) are also referred to second bonding structures.

An array of solder material portions are attached to the metallic bonding structures (418 or 414) on the silicon interposer 400. The array of solder material portions is subsequently used to provide electrical connection between the composite interposer 600 and a packaging substrate and is herein referred to as an array of interposer-substrate (IS) solder material portions 290.

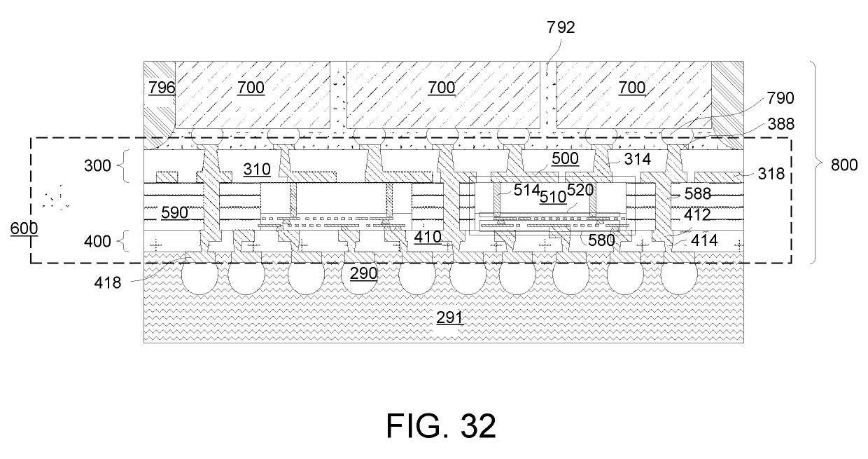

Referring to FIG. 32, an adhesive tape 291 may be attached to the array of IS solder material potions 290. The first carrier wafer 301 may be subsequently detached, and a suitable cleaning process may be performed to remove residual portions of the adhesive material from the physically exposed surfaces of the semiconductor dies 700 and the MC matrix that includes a two-dimensional array of MC die frames 796.

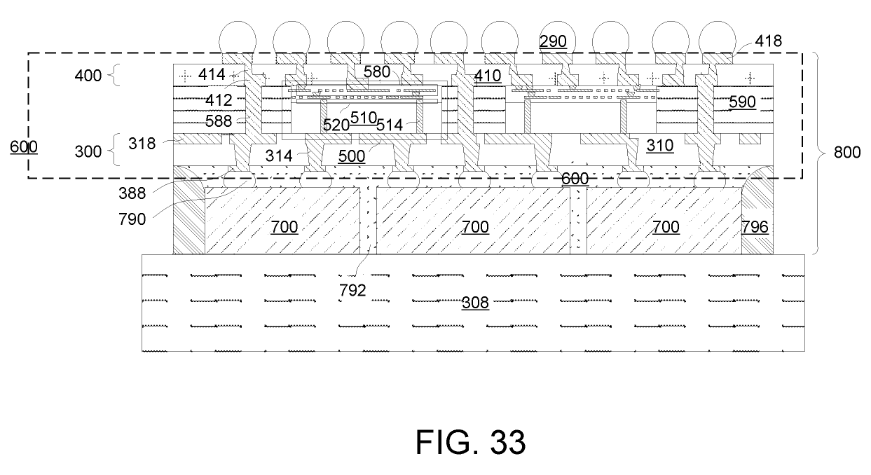

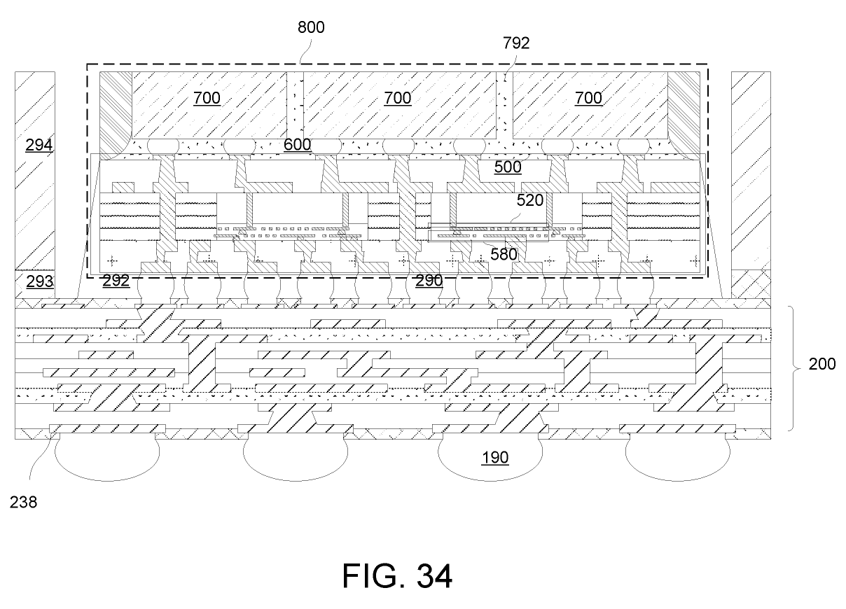

Referring to FIG. 33, the reconstituted wafer including a two-dimensional array of fan-out packages 800 may be mounted onto a dicing frame 308. The adhesive tape 291 may be subsequently removed. The reconstituted wafer may be diced along dicing channels so that the fan-out packages 800 are singulated into discrete structures. The diced fan-out packages 800 may be subsequently detached from the dicing frame 308.

Referring to FIG. 34, the fan-out package 800 including composite interposer 600, the at least one semiconductor die 700, and the MC die frame 796 illustrated in FIG. 33 may be attached to the composite packaging substrate 200 illustrated in FIG. 23. The array of IS solder material portions 290 may be aligned to the array of first substrate bonding pads 238, and a reflow process may be performed to induce bonding between the array of IS solder material portions 290 and the array of first substrate bonding pads 238. Generally, an assembly comprising the at least one in-interposer semiconductor chip 500, the dielectric matrix 590, the organic redistribution structure 300, and the at least one semiconductor die 700 may be attached to the composite packaging substrate 200. A stabilization structure 294 such as a stabilization ring or a stabilization lid may be attached to the composite packaging substrate 200 using an adhesive layer 293 and/or a thermal interface layer (not shown).

Subsequently, the assembly of the fan-out package 800 and the composite interposer 200 may be attached to a printed circuit board (not shown) using the array of SB solder material portions 190.

According to an aspect of the present disclosure, a composite interposer 600 is provided, which comprises at least one in-interposer semiconductor chip 500 including a respective semiconductor circuitry (520, 580) therein, a dielectric matrix 590 laterally surrounding the at least one in-interposer semiconductor chip 500, a silicon interposer 400 located on a first side of the dielectric matrix 590, and an organic redistribution structure 300 located on a second side of the dielectric matrix 590. At least one semiconductor dies 700 may be attached to one of the silicon interposers 400 and the organic redistribution structure 300. A packaging substrate may be attached to another of the silicon interposer 400 and the organic redistribution structure 300.

In one embodiment, the packaging substrate may comprise a composite packaging substrate 200 illustrated in FIGS. 22 and 23, which comprises at least one ceramic layer 210 comprising a respective set of holes therethrough, first dielectric build-up films 220 located on a first side of the at least one ceramic layer 210, second dielectric build-up films 220 located on a second side of the at least one ceramic layer 210, and metal interconnects (314, 318, 388) providing electrical connection through the first dielectric build-up films 220, the at least one ceramic layer 210, and the second dielectric build-up films 220. Generally, an assembly comprising the at least one in-interposer semiconductor chip 500, the dielectric matrix 590, the organic redistribution structure 300, and the at least one semiconductor die 700 (such as a fan-out package 800 of the present disclosure) may be bonded to the composite packaging substrate 200.

Various additional structures derived from the first exemplary structure and/or the second exemplary structure are expressly contemplated herein. For example, an additional interposer may be used to attach one or more additional semiconductor dies to the composite packaging substrate 200 of the present disclosure.

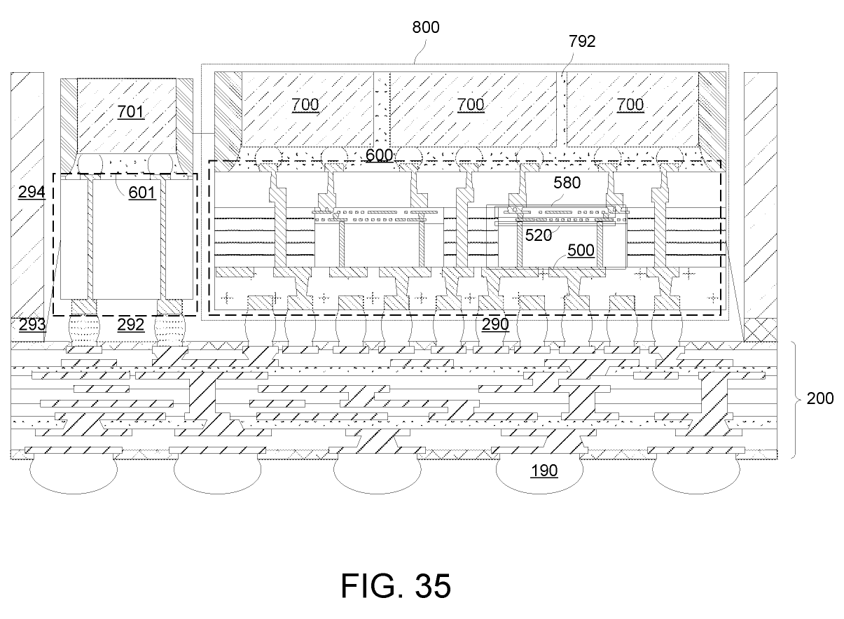

Referring to FIG. 35, a third exemplary chip package structure according to various embodiments of the present disclosure is illustrated, which may be derived from the first exemplary structure or the second exemplary structure by bonding a combination of an additional silicon interposer 601 and at least one additional semiconductor dies 701. The additional silicon interposer 601 may comprise an array of through-silicon via (TSV) structures that are laterally surrounded by, and is electrically isolated from, a silicon substrate of the additional silicon interposer 601. The TSV structures within the additional silicon interposer 601 provide electrically conductive paths through the silicon substrate of the additional silicon interposer 601. The at least one additional semiconductor die 701 is attached to the additional silicon interposer 601 through an array of solder material portions that is laterally surrounded by an additional underfill material portion. In some embodiments, the additional silicon interposer 601 and the at least one additional semiconductor die 701 may be components of an additional fan-out package. The additional silicon interposer 601 may be bonded to the composite packaging substrate 200, and may be laterally spaced from the composite interposer 600. In one embodiment, an underfill material portion 292 may laterally surround, and contact, the composite interposer 600 and the additional silicon interposer 601.

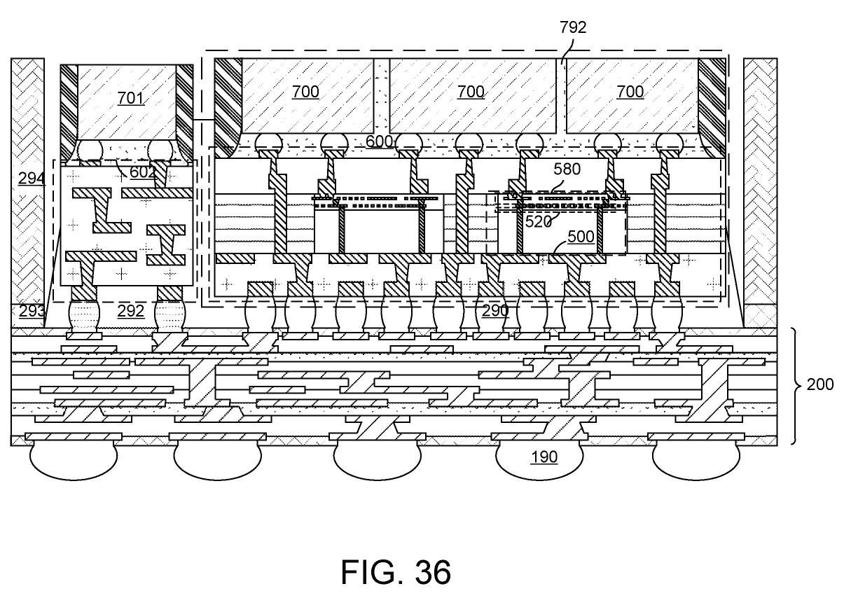

Referring to FIG. 36, a fourth exemplary chip package structure according to various embodiment of the present disclosure is illustrated, which may be derived from the first exemplary structure or the second exemplary structure by bonding a combination of an organic interposer 602 and at least one additional semiconductor dies 701. The organic interposer 602 may comprise polymer-based insulating layers embedding metal interconnects that provide electrical connection between the front side of the organic interposer 602 and the backside of the organic interposer 602. Suitable metal bump structures may be provided on both sides of the organic interposer 602 to facilitate bonding with the at least one additional semiconductor die 701 and the composite packaging substrate 200. The at least one additional semiconductor die 701 is attached to the additional organic interposer 602 through an array of solder material portions that is laterally surrounded by an additional underfill material portion. In some embodiments, the organic interposer 602 and the at least one additional semiconductor die 701 may be components of an additional fan-out package. The organic interposer 602 may be bonded to the composite packaging substrate 200 and may be laterally spaced from the composite interposer 600. In one embodiment, an underfill material portion 292 may laterally surround, and contact, the composite interposer 600 and the organic interposer 602.

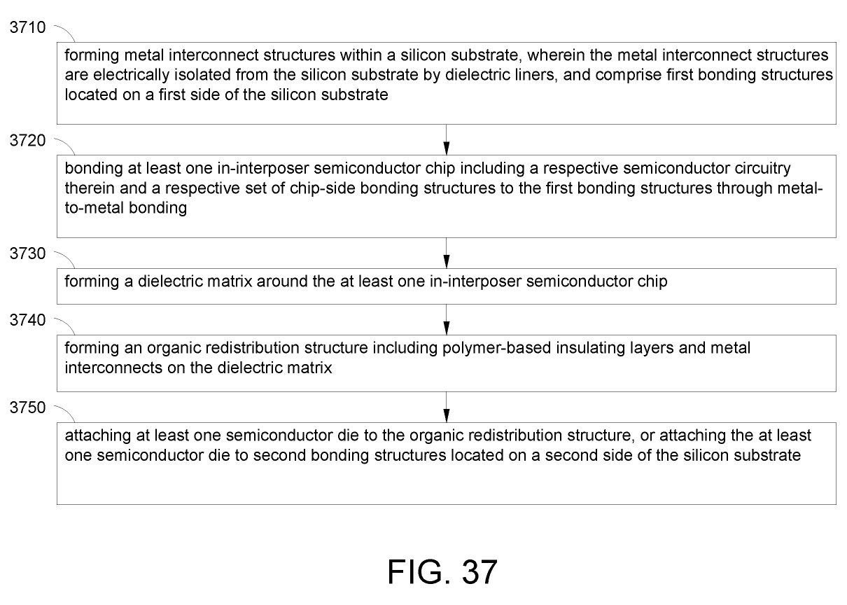

Referring to FIG. 37, a first flowchart illustrates steps for forming an exemplary structure according to an embodiment of the present disclosure.

Referring to step 3710 and FIG. 1, metal interconnect structures (412, 414) may be formed within a silicon substrate 410. The metal interconnect structures (412, 414) are electrically isolated from the silicon substrate 410 by dielectric liners 416, and comprise first bonding structures 412 located on a first side of the silicon substrate 410.

Referring to step 3720 and FIG. 2, at least one in-interposer semiconductor chip 500 including a respective semiconductor circuitry (520, 580) therein and a respective set of chip-side bonding structures (which is a subset of the metal interconnect structures 580) may be bonded to the first bonding structures 412 through metal-to-metal bonding.

Referring to step 3730 and FIGS. 3 and 4, a dielectric matrix 590 may be formed around the at least one in-interposer semiconductor chip 500.

Referring to step 3740 and FIGS. 25, 26, and 11, an organic redistribution structure 300 including polymer-based insulating layers 310 and metal interconnects (314, 318, 388) may be formed on the dielectric matrix 590.

Referring to step 3750 and FIGS. 27 – 36 and 9, at least one semiconductor die 700 may be attached to the organic redistribution structure 300 or to second bonding structures (414 or 418) located on a second side of the silicon substrate 410.

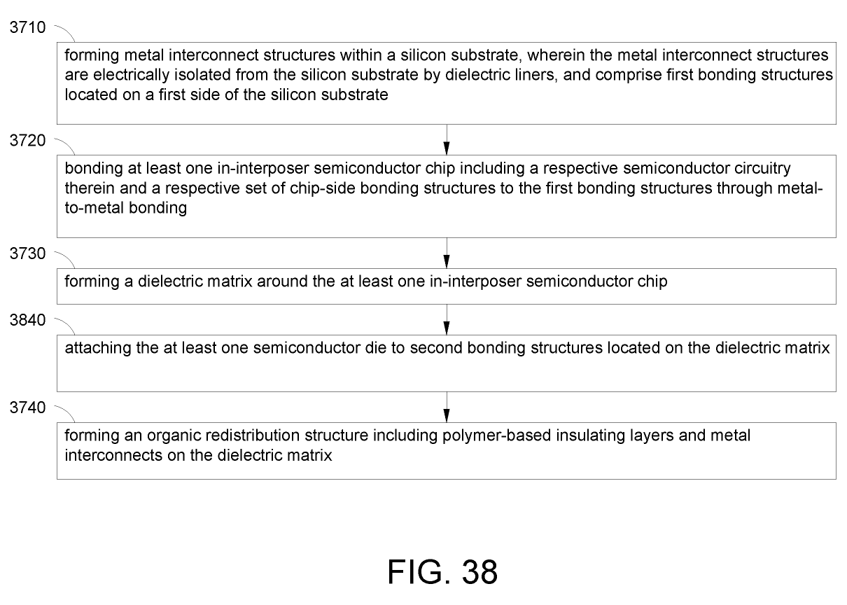

Referring to FIG. 38, a second flowchart illustrates steps for forming an exemplary structure according to an embodiment of the present disclosure.

Referring to step 3710 and FIG. 1, metal interconnect structures (412, 414) may be formed within a silicon substrate 410. The metal interconnect structures (412, 414) are electrically isolated from the silicon substrate 410 by dielectric liners 416 and comprise first bonding structures 412 located on a first side of the silicon substrate 410.

Referring to step 3720 and FIG. 2, at least one in-interposer semiconductor chip 500 including a respective semiconductor circuitry (520, 580) therein and a respective set of chip-side bonding structures (which is a subset of the metal interconnect structures 580) may be bonded to the first bonding structures 412 through metal-to-metal bonding.

Referring to step 3730 and FIGS. 3 and 4, a dielectric matrix 590 may be formed around the at least one in-interposer semiconductor chip 500.

Referring to step 3840 and FIGS. 5 – 9, at least one semiconductor dies 700 may be attached to second bonding structures (414 or 418) located on a second side of the silicon substrate 410.

Referring to step 3740 and FIGS. 10 and 11, an organic redistribution structure 300 including polymer-based insulating layers 310 and metal interconnects (314, 318, 388) may be formed on the dielectric matrix 590.

Referring to all drawings and according to various embodiments of the present disclosure, a chip package structure is provided, which comprises: a composite interposer 600 comprising at least one in-interposer semiconductor chip 500 including a respective semiconductor circuitry (520, 580) therein, a dielectric matrix 590 laterally surrounding the at least one in-interposer semiconductor chip 500, a die-side redistribution structure (400 or 300) located on a first side of the dielectric matrix 590, and a substrate-side redistribution structure (300 or 400) located on a second side of the dielectric matrix 590; and at least one semiconductor die 700 attached to the die-side redistribution structure (400 or 300) through a respective array of solder material portions 790.

In one embodiment, the at least one in-interposer semiconductor chip 500 comprises an input/output control chip, a system-on-chip (SoC) chip, a static random access memory (SRAM) chip, or a dynamic random access memory (DRAM) chip.

In one embodiment, each of the at least one in-interposer semiconductor chip may include a respective semiconductor substrate embedding respective through-substrate via structures therein, and a respective semiconductor circuitry located on the respective semiconductor substrate

In one embodiment, at least one of the die-side redistribution structure (400 or 300) and the substrate-side redistribution structure (300 or 400) comprises a silicon interposer 400 including a silicon substrate 410 and metal interconnect structures (412, 414) located within the silicon substrate 410 and electrically isolated from the silicon substrate 410 by dielectric liners 416. In one embodiment, the at least one in-interposer semiconductor chip 500 comprises chip-side bonding structures that are bonded to bonding structures 412 of the silicon interposer 400 through metal-to-metal bonding.

In one embodiment, the chip package structure comprises through insulator via (TIV) structures 588 extending through the dielectric matrix 590 and connecting a respective pair of a metal interconnect structure (412 or 318) in the die-side redistribution structure (400 or 300) and a metal interconnect structure (318 or 412) in the substrate-side redistribution structure (300 or 400).

In one embodiment, one of the die-side redistribution structure (400 or 300) and the substrate-side redistribution structure (300 or 400) comprises the silicon interposer 400; and another of the die-side redistribution structure (400 or 300) and the package-redistribution structure comprises an organic redistribution structure 300 including polymer-based insulating layers 310 and metal interconnects (314, 318, 388) located within the polymer-based insulating layers 310. In one embodiment, the organic redistribution structure 300 comprises metallic bonding structures 388 facing the at least one semiconductor die 700; and the respective array of solder material portions 790 is bonded to a respective subset of the metallic bonding structures 388.

In one embodiment, the silicon interposer 400 comprises metallic bonding structures (414 or 418) facing the at least one semiconductor dies 700; and the respective array of solder material portions 790 is bonded to a respective subset of the metallic bonding structures (414 or 418).

In one embodiment, the chip package structure comprises a composite packaging substrate 200 bonded to the composite interposer 600. The composite packaging substrate 200 comprises: at least one ceramic layer 210 comprising a respective set of holes therethrough; first dielectric build-up films 220 located on a first side of the at least one ceramic layer 210; second dielectric build-up films 220 located on a second side of the at least one ceramic layer 210; and metal interconnects (214, 224) providing electrical connection through the first dielectric build-up films 220, the at least one ceramic layer 210, and the second dielectric build-up films 220.

According to another aspect of the present disclosure, a chip package structure is provided, which comprises: a composite interposer 600 comprising at least one semiconductor chip 500 including a respective semiconductor circuitry (520, 580) therein, a dielectric matrix 590 laterally surrounding the at least one semiconductor chip 500, a silicon interposer 400 located on a first side of the dielectric matrix 590, and an organic redistribution structure 300 located on a second side of the dielectric matrix 590; at least one semiconductor die 700 attached to one of the silicon interposer 400 and the organic redistribution structure 300; and a packaging substrate attached to another of the silicon interposer 400 and the organic redistribution structure 300.

In one embodiment, the chip package structure comprises: an additional silicon interposer 601 bonded to the packaging substrate and laterally spaced from the composite interposer 600; an underfill material portion 292 laterally surrounding the composite interposer 600 and the additional silicon interposer 601; and at least one additional semiconductor die 701 that is attached to the additional silicon interposer 601.

In one embodiment, the chip package structure comprises: an organic interposer 602 bonded to the packaging substrate and laterally spaced from the composite interposer 600; an underfill material portion 292 laterally surrounding the composite interposer 600 and the organic interposer 602; and at least one additional semiconductor die 701 that is attached to the organic interposer 602.

The various embodiments of the present disclosure may be used to form chip package structures that are smaller than related MCM packages or other packages using a silicon interposer or an organic interposer, while providing more effective heat dissipation through at least one ceramic layer in a composite packaging substrate and reducing thermal performance degradation of the chip package structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a chip package structure, the method comprising:
forming metal interconnect structures within a silicon substrate, wherein the metal interconnect structures are electrically isolated from the silicon substrate by dielectric liners;
bonding an in-interposer semiconductor chip including a respective semiconductor circuitry therein to a first side of the silicon substrate;
forming a dielectric matrix around the in-interposer semiconductor chip;
forming an organic redistribution structure on the dielectric matrix; and
attaching a semiconductor die to the organic redistribution structure or to a second side of the silicon substrate.

2. The method of claim 1, wherein the metal interconnect structures comprise first bonding structures located on the first side of the silicon substrate, and wherein the in-interposer semiconductor chip is bonded to the first bonding structures.

3. The method of claim 2, wherein the in-interposer semiconductor chip comprises chip-side bonding structures that are bonded to the first bonding structures through metal-to-metal bonding.

4. The method of claim 1, wherein the organic redistribution structure includes polymer-based insulating layers and metal interconnects located within the polymer-based insulating layers.

5. The method of claim 1, wherein the in-interposer semiconductor chip comprises a respective semiconductor substrate having respective through-substrate via structures formed therein.

6. The method of claim 1, further comprising:
applying a dielectric fill material around the in-interposer semiconductor chip over the silicon substrate; and
removing portions of the dielectric fill material and the in-interposer semiconductor chip that are distal from the silicon substrate by performing a planarization process, wherein a remaining portion of the dielectric fill material comprises the dielectric matrix.

7. The method of claim 1, further comprising:
attaching a first carrier wafer to the in-interposer semiconductor chip and the dielectric matrix; and
thinning the silicon substrate by removing a portion of the silicon substrate from the second side of the silicon substrate, wherein a subset of the metal interconnect structures is physically exposed upon removal of the portion of the silicon substrate.

8. A method of forming a chip package structure, the method comprising:
forming metal interconnect structures within a silicon substrate, wherein the metal interconnect structures are electrically isolated from the silicon substrate by dielectric liners;
bonding an in-interposer semiconductor chip including a respective semiconductor circuitry therein to a first side of the silicon substrate;
forming a dielectric matrix around the in-interposer semiconductor chip;
forming an organic redistribution structure on the dielectric matrix; and
attaching a semiconductor die to the organic redistribution structure or to a second side of the silicon substrate.

9. The method of claim 8, wherein the semiconductor die is attached to second bonding structures located on the second side of the silicon substrate, and wherein the second bonding structures comprise a subset of the metal interconnect structures or bonding structures formed on the subset of the metal interconnect structures.

10. The method of claim 8, wherein the in-interposer semiconductor chip comprises chip-side bonding structures that are bonded to first bonding structures of the metal interconnect structures through metal-to-metal bonding.

11. The method of claim 8, further comprising forming through insulator via (TIV) structures extending through the dielectric matrix and connecting a metal interconnect structure in the silicon substrate to a metal interconnect structure in the organic redistribution structure.

12. The method of claim 8, further comprising:
attaching a first carrier wafer to the in-interposer semiconductor chip and the dielectric matrix;
forming a molding compound die frame around the semiconductor die;
attaching a second carrier wafer to the semiconductor die and the molding compound die frame; and
detaching the first carrier wafer from the in-interposer semiconductor chip and the dielectric matrix.

13. The method of claim 8, further comprising thinning the silicon substrate by removing a portion of the silicon substrate from the second side of the silicon substrate after attaching the semiconductor die to the organic redistribution structure.

14. The method of claim 8, further comprising:
forming a composite packaging substrate that comprises a ceramic layer and a metal interconnect therethrough; and
bonding an assembly comprising the in-interposer semiconductor chip, the dielectric matrix, the organic redistribution structure, and the semiconductor die to the composite packaging substrate.

15. A method of forming a chip package structure, the method comprising:
forming metal interconnect structures within a silicon substrate, wherein the metal interconnect structures are electrically isolated from the silicon substrate by dielectric liners;
bonding an in-interposer semiconductor chip including a respective semiconductor circuitry therein to a first side of the silicon substrate;
forming a dielectric matrix around the in-interposer semiconductor chip;
forming an organic redistribution structure on the dielectric matrix; and
attaching a semiconductor die to the organic redistribution structure or to a second side of the silicon substrate.

16. The method of claim 15, wherein the in-interposer semiconductor chip comprises a respective semiconductor substrate having respective through-substrate via structures formed therein, and a respective semiconductor circuitry located on the respective semiconductor substrate.

17. The method of claim 15, wherein the silicon substrate and the metal interconnect structures comprise a silicon interposer forming one of a die-side redistribution structure and a substrate-side redistribution structure, and wherein the organic redistribution structure forms another of the die-side redistribution structure and the substrate-side redistribution structure.

18. The method of claim 17, further comprising forming an array of solder material portions on metallic bonding structures of the organic redistribution structure or on metallic bonding structures of the silicon interposer, wherein the metallic bonding structures face the semiconductor die.

19. The method of claim 15, further comprising:
forming a composite packaging substrate comprising a ceramic layer comprising a respective set of holes therethrough, front-side dielectric build-up films located on a front side of the ceramic layer, backside dielectric build-up films located on a backside of the ceramic layer, and metal interconnects providing electrical connection through the front-side dielectric build-up films, the ceramic layer, and the backside dielectric build-up films; and
bonding the composite packaging substrate to the organic redistribution structure or to the silicon substrate.

20. The method of claim 14, further comprising:
bonding an additional interposer to the composite packaging substrate, wherein the additional interposer comprises an additional silicon interposer or an organic interposer, and wherein the additional interposer is laterally spaced from the dielectric matrix;
forming an underfill material portion laterally surrounding the dielectric matrix and the additional interposer; and
attaching an additional semiconductor die to the additional interposer.
